(19) United States
(12) Patent Application Publication
(10) Pub. No.: US 2008/0128729 A1
(43) Pub. Date: Jun. 5, 2008

(54) SEMICONDUCTOR LIGHT EMISSION DEVICE EMITTING POLARIZED LIGHT AND METHOD FOR MANUFACTURING THE SAME

(75) Inventor: Kuniyoshi Okamoto, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/877,416

(22) Filed: Oct. 23, 2007

(30) Foreign Application Priority Data
Oct. 27, 2006 (JP) P2006-292429

(51) Int. Cl. H01L 33/00

(52) U.S. Cl. 257/98; 438/29; 257/E33.068

(57) ABSTRACT

A semiconductor light emission device includes: a nitride semiconductor stack including an active layer capable of emitting light, a growth surface of the nitride semiconductor stack being a substantially nonpolar plane or substantially semipolar plane; and a metallic reflection layer in Schottky contact formed in a surface of the device opposite to a light extraction surface through which the light emitted from the active layer is extracted, the reflection section reflecting the light to the light extraction surface.

### CROSS REFERENCE TO RELATED APPLICATION AND INCORPORATION BY REFERENCE

This application is based upon and claims the benefit of priority from prior Japanese Patent Application No. 2006-292429, filed on Oct. 27, 2006, the entire contents of which are incorporated by reference herein.

### BACKGROUND OF THE INVENTION

1. Field of the Invention

The present invention relates to a semiconductor light emission device having a nitride semiconductor stack.

2. Description of the Related Art

There are known semiconductor light emission devices including various nitride semiconductor stacks having active layers capable of emitting blue light and the like.

Japanese Granted Patent Publication No. 3412563 (Patent Literature 1) discloses a semiconductor light emission device including a nitride semiconductor stack having a plurality of nitride semiconductor layers, such as a GaN layer and an InGaN or AlGaN layer constituting an active layer, stacked on a sapphire substrate. This semiconductor light emission device includes an aluminum nitride reflection layer on the bottom surface of the substrate.

In the semiconductor light emission device of Patent Literature 1, the reflection layer is provided on the bottom surface of the substrate, so that light traveling from the active layer in a direction opposite to a light extraction direction, or toward the substrate, can be reflected and extracted in the light extraction direction. Accordingly, it is possible to extract light, which escapes through a surface facing opposite to the light extraction direction in a conventional device, in the light extraction direction, thus increasing an amount of light extracted in the light extraction direction.

In the aforementioned semiconductor light emission device of Patent Literature 1, the reflection layer is provided to increase the amount of light extracted in the light extraction direction. However, light emitted from the active layer is not polarized, and the polarization ratio of extracted light is low.

### SUMMARY OF THE INVENTION

A semiconductor light emission device according to the present invention includes: a nitride semiconductor stack including an active layer capable of emitting light, a growth surface of the nitride semiconductor stack being a substantially nonpolar plane or substantially semipolar plane; and a metallic reflection layer in Schottky contact which is formed in a surface of the device opposite to a light extraction surface through which the light emitted from the active layer is extracted, the reflection layer reflecting the light to the light extraction surface.

A method for manufacturing a semiconductor light emission device according to the present invention includes: a step of forming a nitride semiconductor stack which includes an active layer capable of emitting light, a growth surface of the nitride semiconductor stack being a substantially nonpolar plane or substantially semipolar plane; and a step of forming a metallic reflection layer in Schottky contact in a surface of the device opposite to a light extraction surface through which the light emitted from the active layer is extracted, the reflection layer reflecting the light to the light extraction surface.

Herein, the substantially nonpolar plane is an idea including a nonpolar plane and a plane having an off angle within ±1 degree from the orientation of the nonpolar plane. The substantially semipolar plane is an idea including a semipolar plane and a plane having an off angle within ±1 degree from the orientation of the semipolar plane.

According to the present invention, the provision of the nitride semiconductor stack whose growth surface is a substantially nonpolar plane or a substantially semipolar plane allows the active layer to emit polarized light. It is therefore possible to increase the polarization ratio of light extracted. Light traveling in the opposite direction to the light extraction surface among the emitted light is generally dispersed by an external casing or the like, thus resulting in reduction in polarization ratio. In the present invention, the provision of the metallic reflection layer in Schottky contact allows the light traveling in the opposite direction to the light extraction surface to be reflected toward the light extraction surface. Accordingly, it is possible to reduce the reduction in polarization ratio due to external dispersion of light radiated through a surface opposite to the light extraction surface. The amount of light extracted through the light extraction surface can be increased while the polarization ratio is increased.

### BRIEF DESCRIPTION OF DRAWINGS

FIG. 1 is a cross-sectional view of a semiconductor light emission device (a light emitting diode) according to a first embodiment.

FIG. 2 is a diagram showing a relation between light emission intensity and wavelength of examples.

FIG. 3 is a diagram showing a relation between light emission intensity and wavelength of comparative examples.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### First Embodiment

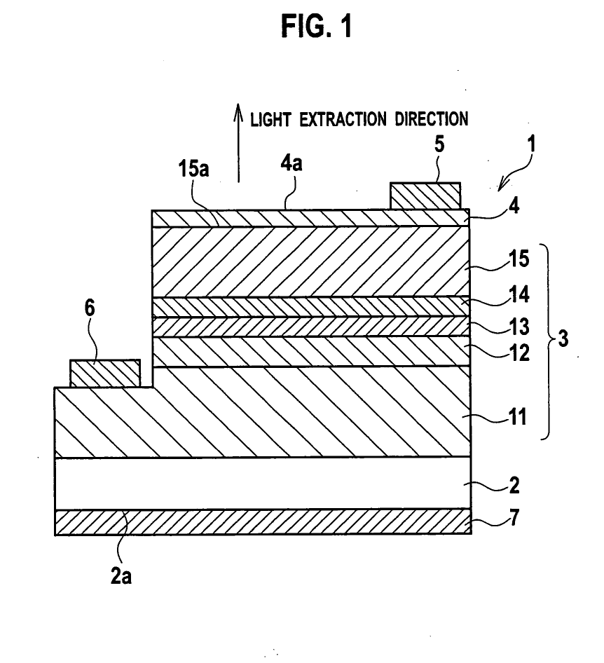

With reference to the drawings, a description is given of a first embodiment of a light emitting diode (LED) to which the present invention is applied. FIG. 1 is a cross-sectional view of a semiconductor light emission device (LED) according to the first embodiment.

As shown in FIG. 1, a semiconductor light emission device 1 includes a substrate 2, a nitride semiconductor stack 3 provided on the substrate 2, an anode electrode 4, a cathode electrode 6, and a reflection layer 7.

The substrate 2 is composed of single-crystal gallium nitride (GaN). The method for manufacturing single-crystal gallium nitride is not particularly limited. On a growth surface of the substrate 2, the nitride semiconductor stack 3 is provided. The growth surface of the substrate 2 is composed of nonpolar m-plane. When the GaN crystalline structure is approximated by a hexagonal crystal of a hexagonal cylinder, m-plane is a surface corresponding to a side surface of the hexagonal cylinder ((10-10) plane, for example). A surface of the substrate 2 facing opposite to the light extraction direction A, or a bottom surface 2a, on which the reflection layer 7 is formed, is mirror-finished so that height of roughness thereof is smaller than wavelength of light emitted from a later-described active layer 12.

The nitride semiconductor stack 3 includes an n-type contact layer 11, the active layer 12, a final barrier layer 13, a p-type electron blocking layer 14, and a p-type contact layer 15 sequentially stacked from the substrate 2 side. As described above, the growth surface of the substrate 2 is composed of m-plane. Accordingly, the growth surface of the nitride semiconductor stack 3 provided on the growth surface of the substrate 2 is also composed of nonpolar m-plane which allows the active layer 12 to emit polarized light.

The n-type contact layer 11 is an about 3 μm or more thick n-type GaN layer doped with silicon having a concentration of about 1×10¹⁸ cm⁻³ as an n-type dopant.

The active layer 12 has a quantum well structure in which five In_{z}Ga_{1-z}N layers doped with silicon (about 3 nm thick) and five GaN layers (about 9 nm thick) are alternately stacked. The active layer 12 emits blue light (wavelength: about 430 nm, for example).

The final barrier layer 13 is composed of an about 40 nm thick GaN layer. As for doping, p-type doping, n-type doping, or non-doping may be employed, but non-doping is preferred.

The p-type electron blocking layer 14 is composed of an about 28 nm thick AlGaN layer doped with magnesium having a concentration of about 3×10¹⁹ cm⁻³ as a p-type dopant.

The p-type contact layer 15 is composed of an about 70 nm thick GaN layer doped with magnesium having a concentration of about 1×10²⁰ cm³ as a p-type dopant. A light extraction side surface 15a of the p-type contact layer 15, which faces opposite to a light extraction direction A, is provided to extract from the nitride semiconductor stack 3 light emitted from the active layer 12. The light extraction side surface 15a is mirror-finished so that roughness thereof is not more than about 100 nm in order to reduce dispersion of light and prevent reduction in polarization ratio. For example, such a flat mirror surface as described above can be obtained by crystal growth.

The anode electrode 4 is composed of a metallic layer including Ni and Au layers sequentially stacked from the p-type contact layer 15 side. The anode electrode 4 is ohmic-connected to the p-type contact layer 15 and formed so as to cover substantially the entire surface of the p-type contact layer 15 so that current passes through the nitride semiconductor stack 3 uniformly in the horizontal direction (the direction orthogonal to the stacking direction). The anode electrode 4 has a thickness of not more than about 200 Å so as to transmit light emitted from the active layer 12. A light extraction surface 4a of the anode electrode 4 is provided to extract light emitted from the active layer 12 and is mirror-finished so that roughness thereof is not more than about 100 nm similarly to the light extraction side surface 15a of the p-type contact layer 15. Such a mirror surface as described above can be obtained using electron beam evaporation, for example. As described above, light emitted from the active layer 12 can be prevented by the mirror-finished light extraction side surface 15a and light extraction surface 4a from dispersing and accordingly extracted with the polarization ratio maintained high. On a part of the anode electrode 4, a connection section 5 including Ti and Au layers stacked is provided.

The cathode electrode 6 includes Ti and Al layers stacked. The cathode electrode 6 is formed in an exposed region of the upper surface of the n-type contact layer 11 and ohmic-connected thereto.

The reflection layer 7 is provided to reflect to the light extraction direction A light traveling in the opposite direction to the light extraction direction A and is formed on the bottom surface 2a of the substrate 2, which is opposite to the light extraction surface 4a. The reflection layer 7 is made of Al and is in Schottky contact with the bottom surface 2a of the substrate 2 to reflect light. The material of the reflection layer 7 is not limited to Al and may be Pt, Ag, or the like.

Next, a description is given of an operation of the aforementioned semiconductor light emission device 1. In this light emission device 1, holes are supplied from the anode electrode 4 while electrons are supplied from the cathode electrode 6. The electrons are injected through the n-type contact layer 11 to the active layer 12, and the holes are injected through the semiconductor layers 13 to 15 to the active layer 12. The electrons and holes injected to the active layer 12 are combined with each other to emit light with a wavelength of about 430 nm. Herein, the light emitted from the active layer 12 is polarized since the growth surface of the nitride semiconductor stack 3 is nonpolar m-plane.

Light traveling in the light extraction direction A among the polarized light is transmitted through the semiconductor layers 13 to 15 and anode electrode 4 to be extracted to the outside. On the other hand, light traveling in the opposite direction to the light extraction direction A is reflected on the reflection layer 7 in the light extraction direction A. Herein, since the bottom surface 2a of the substrate 2, on which the reflection layer 7 is formed, is mirror-finished, light dispersion at the bottom surface 2a can be reduced, and the reduction in polarization ratio can be reduced. Accordingly, the light traveling toward the substrate 2 can be transmitted through the semiconductor layers 13 to 15 and anode electrode 4 to be extracted while not being dispersed and substantially kept polarized.

Next, a description is given of a method for manufacturing the aforementioned semiconductor light emission device.

First, the substrate 2 which is composed of single crystal GaN and has the growth surface being nonpolar m-plane is prepared. Herein, the substrate 2 whose growth surface is nonpolar m-plane is produced as follows: first cutting a single crystal GaN substrate whose growth surface is C-plane; and then polishing the surface thereof by chemical mechanical polishing (CMP) for mirror finishing so that orientation errors related to both orientations (0001) and (11-20) are within ±1 degree, preferably ±0.3 degrees. The thus-obtained substrate 2 includes the growth surface of m-plane and has a few crystal defects such as dislocations or stacking faults. Moreover, roughness of the surface of the substrate 2 can be reduced to the atomic level.

Next, the nitride semiconductor stack 3 is grown on the above-described substrate 2 by MOCVD. Specifically, first, the substrate 2 is put in a processing chamber of an MOCVD apparatus (not shown) and placed on a susceptor capable of heating and rotating. The processing chamber is set to 1/10 to 1 atm, and the atmosphere in the processing chamber is always exhausted.

Next, to grow a GaN layer while controlling roughness of the surface thereof, ammonium gas is supplied with carrier gas (H₂ gas) to the processing chamber in which the substrate 2 is held while the temperature of the processing chamber is increased to about 1000 to 1100° C.

Next, after the temperature of the substrate 2 is increased to about 1000 to 1100° C., ammonium, trimethylgallium, and silane are supplied to the processing chamber with carrier gas to grow the n-type contact layer 11 composed of an n-type GaN layer doped with silicon.

Next, the temperature of the substrate 2 is set to about 700 to 800° C., and then ammonium and trimethylgallium are supplied to the processing chamber with carrier gas to grow a non-doped GaN layer. Subsequently, silane and trimethylindium are supplied together with the above gas to grow an InGaN layer doped with silicon.

These steps of growing the non-doped GaN layer and doped InGaN layer are alternately repeated a predetermined number of times to form the active layer 12 having a quantum well structure. Thereafter, ammonium and trimethylgallium are supplied to the processing chamber with carrier gas to grow the final barrier layer 13 composed of a GaN layer.

Next, the temperature of the substrate 2 is increased to about 1000 to 1100° C., and then ammonium, trimethylgallium, trimethylaluminum, and ethylcyclopentadienylmagnesium are then supplied with carrier gas to grow the p-type electron blocking layer 14 composed of a p-type AlGaN layer doped with magnesium.

Next, ammonium, trimethylgallium, and ethylcyclopentadienylmagnesium are supplied to the processing chamber with carrier gas while the temperature of the substrate 2 is maintained at about 1000 to 1100° C., thus growing the p-type contact layer 15 composed of a GaN layer doped with magnesium. The nitride semiconductor stack 3 is thus completed.

Next, the reflection layer 7 composed of Al is grown on the bottom surface 2a of the substrate 2 using electron beam evaporation or resistance heating with a metal evaporator. Herein, in order to bring the reflection layer 7 and substrate 2 into Schottky contact, annealing and the like are not performed after the reflection layer 7 is formed.

Next, the anode electrode 4 is formed with a metal evaporator using electron beam evaporation or resistance heating. Thereafter, the substrate 2 with the nitride semiconductor stack 3 and reflection layer 7 formed thereon is moved to an etching chamber, and the nitride semiconductor stack 3 is partially plasma-etched so that a part of the n-type contact layer 11 is exposed.

Next, the connecting section 5 and cathode electrode 6 are formed by a metal evaporator using electron beam evaporation or resistance heating. Thereafter, the obtained product is cleaved into each device. The semiconductor light emission device 1 shown in FIG. 1 is thus completed.

Next, a description is given of experiments conducted to prove the effect of the semiconductor light emission device according to the present invention.

First, as examples, semiconductor light emission devices provided with 200 nm thick reflection layers on bottom surfaces of substrates opposite to the light extraction surfaces were produced. Furthermore, as Example A1, one of the produced devices was provided with a polarization plate whose polarization direction was parallel to the polarization direction of polarized light emitted from the active layer. As Example B1, the other one of the produced devices was provided with a polarization plate whose polarization direction was perpendicular to the polarization direction of polarized light emitted from the active layer.

Next, as comparative examples, semiconductor light emission devices having the same structure as that of the examples other than including no reflection layers on the bottom surfaces of the substrates were produced. Furthermore, as Comparative Example A2, one of the produced light emission devices was provided with a polarization plate whose polarization direction was parallel to the polarization direction of polarized light emitted from the active layer. As Comparative Example B2, the other one of the produced light emission devices was provided with a polarization plate whose polarization direction was perpendicular to the polarization direction of polarized light emitted from the active layer.

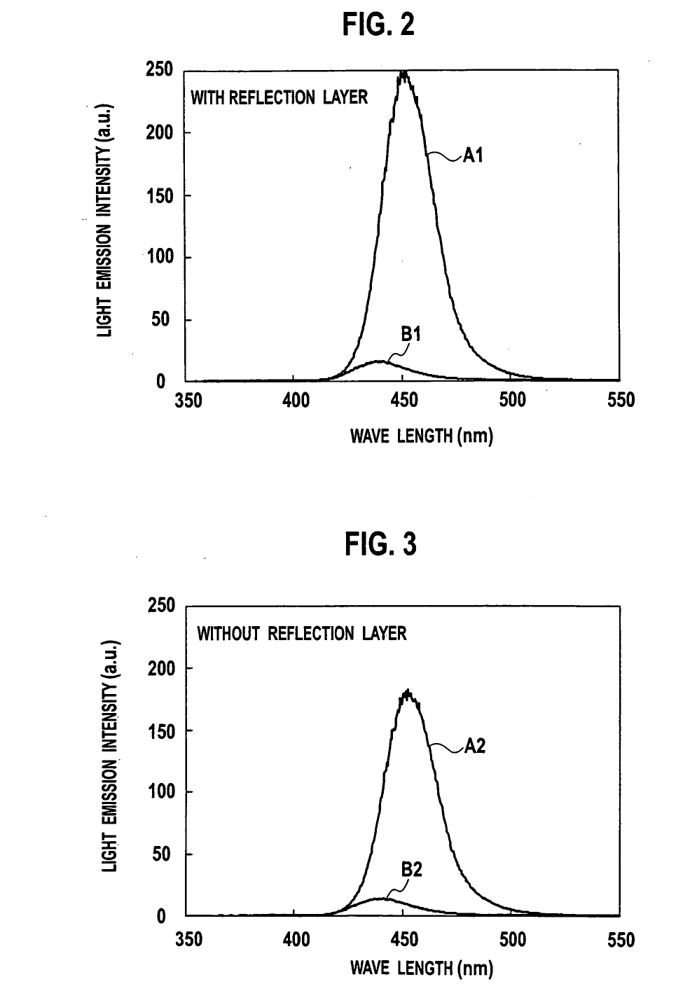

Subsequently, light emission intensity of each device was measured. FIG. 2 shows results of measurement of the light emission intensities of Examples A1 and B1 for each wavelength, and FIG. 3 shows results of measurement of the light emission intensities of Comparative Examples A2 and B2 for each wavelength.

Herein, a polarization ratio ρ₁ of Examples A1 and B1 was:

ρ₁=(I_{A1}−I_{B1})/(I_{A1}+I_{B1})=0.87

and, a polarization ratio ρ₂ of Examples A2 and B2 was:

ρ₂=(I_{A2}−I_{B2})/(I_{A2}+I_{B2})=0.84

Herein, I_{A1}, I_{B1}, I_{A2}, and I_{B2} are light intensities of Examples A1 and B1 and Comparative Examples A2 and B2 based on the measured light emission intensities, respectively. As a result, it was proved that provision of the reflection layer increased the polarization ratio by 0.03.

As described above, the semiconductor light emission device 1 according to the first embodiment includes the nitride semiconductor stack 3 whose growth surface is nonpolar m-plane, and polarized light is emitted from the active layer 12. Light traveling in the opposite direction to the light extraction direction A among the emitted light is generally radiated through the bottom surface of the substrate and then dispersed by an external casing or the like, thus resulting in reduction in polarization ratio. However, in the semiconductor light emission device 1 according to the first embodiment, the reflection layer 7 is provided on the bottom surface 2a of the substrate 2, so that light traveling in the opposite direction to the light extraction direction A can be reflected in the light extraction direction A. It is therefore possible to prevent reduction in polarization ratio due to external dispersion of light radiated through the bottom surface 2a of the substrate 2.

Accordingly, the amount of light extracted through the light extraction surface 4a can be increased, and the polarization ratio of the light extracted through the light extraction surface 4a can be increased. Furthermore, mirror finishing of the bottom surface 2a of the substrate 2 can reduce dispersion of light at the bottom surface 2a when the light is incident from the substrate 2 to the reflection layer 7, thus increasing the polarization ratio of extracted light.

As described above, the semiconductor light emission device 1 can provide light with a high polarization ratio. In the case of applying the semiconductor light emission device 1 to a light source of a liquid crystal display, therefore, one of polarization filters to polarize light can be omitted. Alternatively, an amount of light transmitted through the polarization filters can be increased.

### Other Embodiments

Hereinabove, the present invention is described in detail using the embodiment but is not limited to the embodiment described in this specification. The scope of the present invention is determined based on the scope of claims and their equivalents. In the following, a description is given of modifications of the aforementioned embodiments partially modified.

For example, the materials, thickness, and concentrations of the dopants of each layer can be properly changed.

The aforementioned embodiment is an example of the present invention applied to a light emitting diode, but the present invention may be applied to another device such as a laser.

In the aforementioned embodiment, the growth surface of the substrate 2 is m-plane. However, the growth surface of the substrate is not limited to m-plane and may be a substantially nonpolar plane or substantially semipolar plane capable of polarizing light emitted from the active layer. Herein, the substantially nonpolar plane is an idea including a nonpolar plane and a plane with an off angle within ±1 degree from the orientation of the nonpolar plane. The substantially semipolar plane is an idea including a semipolar plane and a plane having an off angle within ±1 degree from the orientation of the semipolar plane. Herein, a brief description is given of the crystalline structure and planes of GaN constituting the substrate. The crystalline structure of GaN is approximated by a hexagonal system of hexagonal cylinder type. The plane whose normal is the C axis along the axis of a hexagonal cylinder is C-plane (001). In the crystalline structure of GaN, as conventionally known, the polarization direction is equal to the direction of C-axis, and C-plane has different characteristics between the +C axis side and −C axis side. Accordingly, C-plane is a polar plane. On the other hand, each side surface of the hexagonal cylinder is m-plane (10-10), and a plane including a pair of ridges not adjacent to each other is a-plane (11-20). These crystalline planes are perpendicular to C-plane and orthogonal to the polarization direction. Accordingly, m-plane and a-plane are nonpolar. Moreover, the crystalline plane tilted at an angle other than 90 degrees diagonally intersects with the polarization direction and is therefore a semipolar plane having some polarity. Concrete examples of the semipolar plane are (10-1-1), (10-1-3), (11-22), (11-24), and (10-12) planes.

The material constituting the substrate is not limited to single crystal GaN and may be a sapphire substrate whose primary face is m-plane or a-plane, a spinel substrate whose primary face is (100) or (110) plane, a SiC substrate whose primary face is m-plane, a LiAlO₂ substrate, or the like.

What is claimed is:

1. A semiconductor light emission device comprising:
a nitride semiconductor stack including an active layer capable of emitting light, a growth surface of the nitride semiconductor stack being a substantially nonpolar plane or substantially semipolar plane; and
a metallic reflection layer in Schottky contact which is formed in a surface of the device opposite to a light extraction surface through which the light emitted from the active layer is extracted, the reflection layer reflecting the light to the light extraction surface.

2. The semiconductor light emission device of claim 1, wherein
the surface on which the reflection layer is formed is a mirror surface.

3. The semiconductor light emission device of claim 1, wherein
the reflection layer includes any one of Al, Pt, or Ag.

4. The semiconductor light emission device of claim 1, wherein
the nitride semiconductor stack has a hexagonal crystal structure, and
a growth surface of the nitride semiconductor stack is m-plane.

5. A method for manufacturing a semiconductor light emission device, the method comprising:
a step of forming a nitride semiconductor stack which includes an active layer capable of emitting light, a growth surface of the nitride semiconductor stack being a substantially nonpolar plane or substantially semipolar plane; and
a step of forming a metallic reflection layer in Schottky contact in a surface of the device opposite to a light extraction surface through which the light emitted from the active layer is extracted, the reflection layer reflecting the light to the light extraction surface.

6. The method of claim 5, wherein
the surface in which the reflection layer is formed is mirror finished.

7. The method of claim 5, wherein
the reflection section is formed of any one of Al, Pt, and Ag.

8. The method of claim 5, wherein
the nitride semiconductor stack is formed on a substrate having a hexagonal crystal structure whose growth surface is m-plane.
